(19) United States
(12) Patent Application Publication
(10) Pub. No.: US 2025/0351694 A1
(43) Pub. Date: Nov. 13, 2025

(54) DISPLAY APPARATUS

(71) Applicant: Samsung Display Co., Ltd., Yongin-si (KR)

(72) Inventors: Soohong Cheon, Yongin-si (KR); Kyeuk Lee, Yongin-si (KR)

(21) Appl. No.: 19/203,812

(22) Filed: May 9, 2025

(30) Foreign Application Priority Data
May 10, 2024 (KR) 10-2024-0062187

(51) Int. Cl. H10K 59/131

(52) U.S. Cl. CPC H10K 59/131

(57) ABSTRACT

A display apparatus includes a substrate including a display area, and a peripheral area outside the display area, a driving voltage input in the peripheral area, a first vertical common voltage line and a second vertical common voltage line in the display area, and extending in a first direction, the second vertical common voltage line being at an edge of the display area, and common voltage inputs in the peripheral area, spaced apart from the driving voltage input, and including a common voltage input at an edge of the peripheral area including a protrusion extending toward the display area and extending to the second vertical common voltage line.

### CROSS-REFERENCE TO RELATED APPLICATION

The present application claims priority to, and the benefit of, Korean Patent Application No. 10-2024-0062187, filed on May 10, 2024, in the Korean Intellectual Property Office, the disclosure of which is incorporated by reference herein in its entirety.

### BACKGROUND

### 1. Field

One or more embodiments relate to a display apparatus.

### 2. Description of the Related Art

Display apparatuses visually display data. A display apparatus may provide an image by using light-emitting diodes. Display apparatuses have been used for various purposes, and various designs have been attempted to improve the quality of display apparatuses.

### SUMMARY

One or more embodiments include a display apparatus.

Additional aspects will be set forth in part in the description which follows and, in part, will be apparent from the description, or may be learned by practice of the presented embodiments.

According to one or more embodiments, a display apparatus includes a substrate including a display area, and a peripheral area outside the display area, a driving voltage input in the peripheral area, a first vertical common voltage line and a second vertical common voltage line in the display area, and extending in a first direction, the second vertical common voltage line being at an edge of the display area, and common voltage inputs in the peripheral area, spaced apart from the driving voltage input, and including a common voltage input at an edge of the peripheral area including a protrusion extending toward the display area and extending to the second vertical common voltage line.

The protrusion may be integral with the second vertical common voltage line.

The protrusion may be at a same layer as the second vertical common voltage line.

The driving voltage input may include a driving voltage input at the edge of the peripheral area, and a driving voltage input at a central portion of the peripheral area, wherein a maximum length of the driving voltage input at the edge of the peripheral area in a second direction crossing the first direction is less than a maximum length of the driving voltage input at the central portion of the peripheral area in the second direction.

The second vertical common voltage line may be closer to the peripheral area than the first vertical common voltage line.

The driving voltage input may be provided in plurality, wherein the driving voltage inputs and the common voltage inputs are alternately arranged along a second direction crossing the first direction.

The display apparatus may further include a vertical driving voltage line in the display area, and extending in the first direction.

The vertical driving voltage line may be integral with the driving voltage input.

The vertical driving voltage line may be at a same layer as the driving voltage input.

The first vertical common voltage line may be electrically connected to one of the common voltage inputs through a contact hole.

The display apparatus may further include a horizontal common voltage line in the display area, extending in a second direction crossing the first direction, and electrically connected to the first vertical common voltage line or the second vertical common voltage line.

The display apparatus may further include a horizontal driving voltage line in the display area, extending in the second direction, and electrically connected to the vertical driving voltage line.

According to one or more embodiments, a display apparatus includes a substrate including a display area, and a peripheral area outside the display area, a driving voltage input in the peripheral area, common voltage inputs in the peripheral area, and spaced apart from the driving voltage input, and a first vertical common voltage line in the display area, extending in a first direction, and integral with and extending from one of the common voltage inputs at an edge of the peripheral area.

The display apparatus may further include a second vertical common voltage line in the display area, extending in the first direction, and electrically connected to one of the common voltage inputs at a central portion of the peripheral area.

The first vertical common voltage line, the second vertical common voltage line, and the common voltage inputs may be at a same layer.

The second vertical common voltage line and one of the common voltage inputs at the central portion of the peripheral area may be electrically connected to each other through a contact hole.

The first vertical common voltage line may be closer to the peripheral area than the second vertical common voltage line.

The display apparatus may further include a vertical driving voltage line in the display area and extending in the first direction.

The first vertical common voltage line may be integral with the driving voltage input.

The driving voltage input may include a driving voltage input at the edge of the peripheral area, and a driving voltage input at a central portion of the peripheral area, wherein a maximum length of the driving voltage input at the edge of the peripheral area in a second direction crossing the first direction is less than a maximum length of the driving voltage input at the central portion of the peripheral area in the second direction.

### BRIEF DESCRIPTION OF THE DRAWINGS

The above and other aspects of embodiments will be more apparent from the following description taken in conjunction with the accompanying drawings, in which:

FIG. 1 is a perspective view schematically illustrating a display apparatus, according to one or more embodiments;

FIG. 2 is a cross-sectional view schematically illustrating each sub-pixel of a display apparatus, according to one or more embodiments;

FIG. 3 is a view illustrating each optical unit of a color conversion-transmissive layer of FIG. 2;

FIG. 4 is an equivalent circuit diagram illustrating a light-emitting diode included in a display apparatus and a sub-pixel circuit electrically connected to the light-emitting diode, according to one or more embodiments;

FIG. 5 is a plan view schematically illustrating a display apparatus, according to one or more embodiments; and

FIG. 6 is an enlarged plan view schematically illustrating a portion A of FIG. 5.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc.,

may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

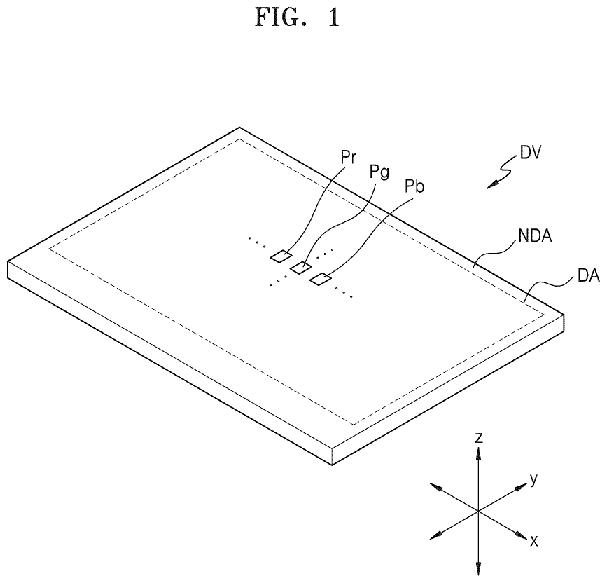

FIG. 1 is a perspective view schematically illustrating a display apparatus, according to one or more embodiments.

Referring to FIG. 1, a display apparatus DV may include a display area DA, and a non-display area NDA (e.g., a peripheral area) outside the display area DA.

The display apparatus DV may provide an image through an array of sub-pixels that are two-dimensionally arranged in a plane in the display area DA. The plurality of sub-pixels may include a red sub-pixel Pr, a green sub-pixel Pg, and a blue sub-pixel Pb. The red sub-pixel Pr, the green sub-pixel Pg, and the blue sub-pixel Pb are areas where red light, green light, and blue light may be respectively emitted, and the display apparatus DV may provide an image by using light emitted from the sub-pixels.

The non-display area NDA where an image is not provided may entirely surround the display area DA (e.g., in plan view). A driver or a voltage wiring for providing an electrical signal or power to sub-pixel circuits may be located in the non-display area NDA. A pad to which an electronic device or a printed circuit board may be electrically connected may be included in the non-display area NDA.

The display area DA may have a polygonal shape. For example, the display area DA may have a rectangular shape in which a horizontal length is greater than a vertical length as shown in FIG. 1. Alternatively, the display area DA may have a rectangular shape in which a horizontal length is less than a vertical length, or may have a square shape. Alternatively, the display area DA may have any of various shapes such as an elliptical shape or a circular shape.

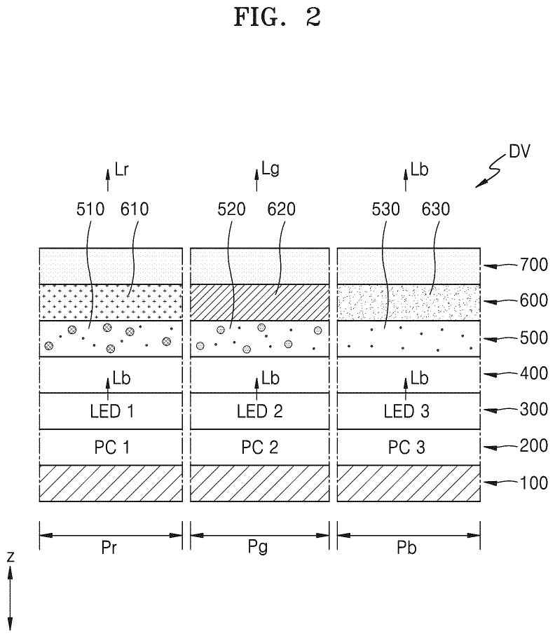

FIG. 2 is a cross-sectional view schematically illustrating each sub-pixel of a display apparatus, according to one or more embodiments.

Referring to FIG. 2, the display apparatus DV may include a circuit layer 200 on a substrate 100. The circuit layer 200 may include first to third sub-pixel circuits PC1, PC2, and PC3, and the first to third sub-pixel circuits PC1, PC2, and PC3 may be respectively electrically connected to first to third light-emitting diodes LED1, LED2, and LED3 of a light-emitting diode layer 300.

Each of the first to third light-emitting diodes LED1, LED2, and LED3 may include an organic light-emitting diode including an organic material. In one or more other embodiments, each of the first to third light-emitting diodes LED1, LED2, and LED3 may include an inorganic light-emitting diode including an inorganic material. The inorganic light-emitting diode may include a PN junction diode including inorganic semiconductor-based materials. When a voltage is applied to a PN junction diode in a forward direction, holes and electrons may be injected, and energy generated by recombination of the holes and electrons may be converted into light energy to emit light of a corresponding color. The inorganic light-emitting diode may have a width of several to hundreds of micrometers or several to hundreds of nanometers. In some embodiments, each of the first to third light-emitting diodes LED1, LED2, and LED3 may be a light-emitting diode including quantum dots. As described above, an emission layer of each of the first to third light-emitting diodes LED1, LED2, and LED3 may include an organic material, may include an inorganic material, may include quantum dots, may include an organic material and quantum dots, or may include an inorganic material and quantum dots.

The first to third light-emitting diodes LED1, LED2, and LED3 may emit light of the same color. For example, the first to third light-emitting diodes LED1, LED2, and LED3 may emit light (e.g., blue light Lb) having a wavelength belonging to a first wavelength band. The first wavelength band may be about 450 nm to about 495 nm. The light (e.g., the blue light Lb) emitted from the first to third light-emitting diodes LED1, LED2, and LED3 may pass through an encapsulation layer 400 on the light-emitting diode layer 300, and may pass through a color conversion-transmissive layer 500.

The color conversion-transmissive layer 500 may include optical units through which the light (e.g., the blue light Lb) emitted from the light-emitting diode layer 300 is transmitted after color conversion or without color conversion. For example, the color conversion-transmissive layer 500 may include color converters (e.g., color conversion units) for converting the light (e.g., the blue light Lb) emitted from the light-emitting diode layer 300 into light of another color, and a transmissive area (e.g., transmissive unit) for transmitting the light (e.g., the blue light Lb) emitted from the light-emitting diode layer 300 without color conversion. The color conversion-transmissive layer 500 may include a first color converter 510 corresponding to the red sub-pixel Pr, a second color converter 520 corresponding to the green sub-pixel Pg, and a transmissive area 530 corresponding to the blue sub-pixel Pb. The first color converter 510 may convert the light (e.g., the blue light Lb) having the wavelength belonging to the first wavelength band into light (e.g., red light Lr) having a wavelength belonging to a second wavelength band. The second wavelength band may be about 630 nm to about 780 nm. The second color converter 520 may convert the light (e.g., the blue light Lb) having the wavelength belonging to the first wavelength band into light (e.g., green light Lg) having a wavelength belonging to a third wavelength band. The third wavelength band may be about 495 nm to about 570 nm. The transmissive area 530 may transmit the light (e.g., blue light) having the wavelength belonging to the first wavelength band without conversion. However, the disclosure is not limited thereto, and a wavelength band to which light (e.g., the blue light Lb) emitted from the light-emitting diode layer 300 and converted by the color conversion-transmissive layer 500 belongs, and a wavelength band to which a wavelength after conversion belongs may be modified differently.

The color layer 600 may be located on the color conversion-transmissive layer 500 (as used herein, “located on” may mean “above”). The color layer 600 may include first to third color filters 610, 620, and 630 of different colors. For example, the first color filter 610 may be a red color filter through which only light having a wavelength belonging to a band of about 630 nm to about 780 nm passes. The second color filter 620 may be a green color filter through which only light having a wavelength belonging to a band of about 495 nm to about 570 nm passes. The third color filter 630 may be a blue color filter through which only light having a wavelength belonging to a band of about 450 nm to about 495 nm passes.

In one or more embodiments, a black matrix may be located between the first to third color filters 610, 620, and 630 when necessary. In one or more other embodiments, the first color filter 610 may have openings corresponding to the green sub-pixel Pg and the blue sub-pixel Pb, the second color filter 620 may have openings corresponding to the red sub-pixel Pr and the blue sub-pixel Pb, and the third color filter 630 may have openings corresponding to the red sub-pixel Pr and the green sub-pixel Pg. In areas other than the openings respectively corresponding to the red sub-pixel Pr, the green sub-pixel Pg, and the blue sub-pixel Pb, an overlapping portion between the first to third color filters 610, 620, and 630 may function as a black matrix.

Light color-converted and light transmitted through the color conversion-transmissive layer 500 may have improved color purity while passing through the first to third color filters 610, 620, and 630. Also, the color layer 600 may reduce, prevent, or minimize external light (e.g., light incident on the display apparatus DV from the outside of the display apparatus DV) from being reflected and viewed by a user.

A light-transmitting base layer 700 may be provided on the color layer 600. The light-transmitting base layer 700 may include glass or a light-transmitting organic material. The light-transmitting base layer 700 may include a light-transmitting organic material such as an acrylic resin.

In one or more embodiments, the light-transmitting base layer 700 is a substrate, and the color layer 600 and the color conversion-transmissive layer 500 may be formed on the light-transmitting base layer 700, and then the color conversion-transmissive layer 500 may be integrated to face the encapsulation layer 400.

In one or more other embodiments, the color conversion-transmissive layer 500 and the color layer 600 may be sequentially formed on the encapsulation layer 400, and then the light-transmitting base layer 700 may be formed by being directly applied to and cured on the color layer 600. In some embodiments, other optical films, for example, an anti-reflection (AR) film, may be located on the light-transmitting base layer 700.

The display apparatus DV having the above structure may include an electronic device capable of displaying a moving image or a still image, such as a television, a billboard, a screen for a movie theater, a monitor, a tablet PC, or a laptop.

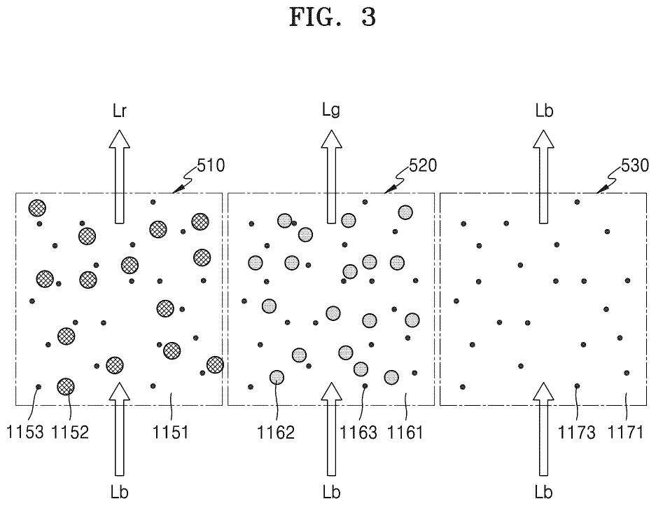

FIG. 3 is a view illustrating each optical unit of the color conversion-transmissive layer of FIG. 2.

The first color converter 510 may convert incident blue light Lb into red light Lr. As shown in FIG. 3, the first color converter 510 may include a first photosensitive polymer 1151, and first quantum dots 1152 and first scattering particles 1153 dispersed in the first photosensitive polymer 1151.

The first quantum dots 1152 may be excited by the blue light Lb to isotropically emit the red light Lr having a longer wavelength than a wavelength of the blue light. The first photosensitive polymer 1151 may be an organic material having light transmission.

A quantum dot may refer to crystals of a semiconductor compound, and may include any material capable of emitting light having various emission wavelengths according to the size of the crystal. The diameter of the quantum dot may be, for example, about 1 nm to about 10 nm.

Quantum dots may be synthesized by using a wet chemical process, a metal organic chemical vapor deposition process, a molecular beam epitaxy process, or the like. The wet chemical process is a method of mixing an organic solvent with a precursor material, and then growing quantum dot crystals. In the wet chemical process, because the organic solvent naturally functions as a dispersant on quantum dot crystal surfaces, and because the organic solvent controls the growth of the crystals when the crystals are grown, the wet chemical process is easier than a vapor deposition method, such as organic metal chemical vapor deposition (MOCVD) or molecular beam epitaxy (MBE). Also, the wet chemical process is an inexpensive process, and may control the growth of quantum dot particles.

Such quantum dots may include a Group III-VI semiconductor compound, a Group II-VI semiconductor compound, a Group III-V semiconductor compound, a Group I-III-VI semiconductor compound, a Group IV-VI semiconductor compound, a Group IV element or compound, or any combination thereof.

Examples of the Group III-VI semiconductor compound may include a binary compound, such as GaS, GaSe, GazSe₃, GaTe, InS, InSe, In₂Se₃, or InTe, a ternary compound, such as InGaS₃ or InGaSe₃, and/or any combination thereof.

Examples of the Group II-VI semiconductor compound may include a binary compound, such as CdS, CdSe, CdTe, ZnS, ZnSe, ZnTe, ZnO, HgS, HgSe, HgTe, MgSe, or MgS, a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, or MgZnS, a quaternary compound, such as CdZnSeS, CdZnSeTe, CdZnSTe, CdHgSeS, CdHgSeTe, CdHgSTe, HgZnSeS, HgZnSeTe, or HgZnSTe, and/or any combination thereof.

Examples of the Group III-V semiconductor compound may include a binary compound, such as GaN, GaP, GaAs, GaSb, AlN, AlP, AlAs, AlSb, InN, InP, InAs, or InSb, a ternary compound, such as GaNP, GaNAs, GaNSb, GaP As, GaPSb, AlNP, AlNAs, AlNSb, AlPAs, AlPSb, InGaP, InNP, InAlP, InNAs, InNSb, InPAs, InPSb, or GaANP, a quaternary compound, such as GaAlNAs, GaAlNSb, GaAlP As, GaAlPSb, GalnNP, GalnNAs, GalnNSb, GalnPAs, GaInPSb, InAlNP, InAlNAs, InAlNSb, InAlPAs, or InAlPSb, and/or any combination thereof. The Group III-V semiconductor compound may further include a Group II element. Examples of the Group III-V semiconductor compound further including the Group II element may include InZnP, InGaZnP, and InAlZnP.

Examples of the Group I-III-VI semiconductor compound may include a ternary compound, such as AgInS, AgInS₂, CuInS, CuInS₂, CuGaO₂, AgGaO₂, or AgAlO₂, and/or any combination thereof.

Examples of the Group IV-VI semiconductor compound may include a binary compound, such as SnS, SnSe, SnTe, PbS, PbSe, or PbTe, a ternary compound, such as SnSeS, SnSeTe, SnSTe, PbSeS, PbSeTe, PbSTe, SnPbS, SnPbSe, or SnPbTe, a quaternary compound, such as SnPbSSe, SnPbSeTe, or SnPbSTe, and/or any combination thereof.

Examples of the Group IV element or compound may include a single-element compound, such as Si or Ge, a binary compound, such as SiC or SiGe, and/or any combination thereof.

Elements included in a multi-element compound, such as a binary compound, a ternary compound, or a quaternary compound, may exist in particles at a uniform or non-uniform concentration.

A quantum dot may have a core-shell structure or a single structure having a uniform element concentration in the quantum dot. For example, a material included in a core and a material included in a shell may be different from each other. The shell of the quantum dot may serve as a protective layer for maintaining semiconductor characteristics by reducing or preventing chemical denaturation of the core and/or a charging layer for providing electrophoretic characteristics to the quantum dot. The shell may have a single or multi-layer structure. An interface between the core and the shell may have a concentration gradient in which a concentration of an element in the shell gradually decreases toward the center.

Examples of the shell of the quantum dot may include an oxide of a metal or a non-metal, a semiconductor compound, and a combination thereof. Examples of the oxide of the metal or the non-metal may include a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, a ternary compound, such as MgAl₂O₄, CoFe₂O₄, NiFe₂O₄, or CoMn₂O₄, and/or any combination thereof. Examples of the semiconductor compound may include, as described above, a Group III-VI semiconductor compound, a Group II-VI semiconductor compound, a Group III-V semiconductor compound, a Group I-III-VI semiconductor compound, a Group IV-VI semiconductor compound, and/or any combination thereof. Examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or any combination thereof.

A quantum dot may have a full width at half maximum (FWHM) of an emission wavelength spectrum of about 45 nm or less, for example about 40 nm or less, and for another example about 30 nm or less. When the FWHM is in this range, color purity or color reproducibility may be improved. Also, because light emitted through the quantum dot is emitted in all directions, an optical viewing angle may be improved.

Also, for example, a quantum dot may be a spherical, pyramid, multi-arm, or cubic-shaped nano particle, nano-tube, nano-wire, nano-fiber, or nano-plate particle.

Because an energy band gap may be adjusted by adjusting a size of a quantum dot, light of various wavelength bands may be obtained through a quantum dot emission layer. Accordingly, a light-emitting device for emitting light having various wavelengths may be realized by using quantum dots having different sizes. In detail, a size of a quantum dot may be selected to emit red light, green light, and/or blue light. Also, a size of a quantum dot may be selected to emit white light by combining light of various colors.

The first scattering particles 1153 may scatter the blue light Lb not absorbed by the first quantum dots 1152 so that more first quantum dots 1152 are excited, thereby improving color conversion efficiency. The first scattering particles 1153 may be, for example, metal oxide particles or organic particles. Examples of the metal oxide for scattering particles may include titanium oxide (TiO₂), zirconium oxide (ZrO₂), aluminum oxide (Al₂O₃), indium oxide (In₂O₃), zinc oxide (ZnO), and/or tin oxide (SnO₂), and examples of the organic material for scattering particles may include an acrylic resin and/or a urethane resin. The scattering particles may scatter light in several directions regardless of an angle of incidence without substantially converting a wavelength of incident light. Accordingly, the scattering particles may improve side visibility of the display apparatus.

The second color converter 520 may convert blue light Lb into green light Lg. As shown in FIG. 3, the second color converter 520 may include a second photosensitive polymer 1161, and second quantum dots 1162 and second scattering particles 1163 dispersed in the second photosensitive polymer 1161.

The second quantum dots 1162 may be excited by the blue light Lb to isotropically emit the green light Lg having a longer wavelength than a wavelength of the blue light. The second photosensitive polymer 1161 may be an organic material having light transmission.

The second scattering particles 1163 may scatter the blue light not absorbed by the second quantum dots 1162 so that more second quantum dots 1162 are excited, thereby improving color conversion efficiency. The description of the first quantum dots 1152 and the first scattering particles 1153 may apply to the second quantum dots 1162 and the second scattering particles 1163, and thus, a repetitive description of the second quantum dots 1162 and the second scattering particles 1163 will be omitted.

In some embodiments, the first quantum dots 1152 and the second quantum dots 1162 may be the same material. In this case, sizes of the first quantum dots 1152 may be greater than sizes of the second quantum dots 1162.

The transmissive area 530 may transmit blue light Lb without converting the blue light Lb incident on the transmissive area 530. Accordingly, the transmissive area 530 does not include quantum dots. As shown in FIG. 3, the transmissive area 530 may include a third photosensitive polymer 1171 in which third scattering particles 1173 are dispersed. The third photosensitive polymer 1171 may be an organic material having light transmission, such as a silicon resin or an epoxy resin, and may be the same material as the first and second photosensitive polymers 1151 and 1161.

The third scattering particles 1173 may scatter and emit the blue light Lb, and may be the same material as the first and second scattering particles 1153 and 1163.

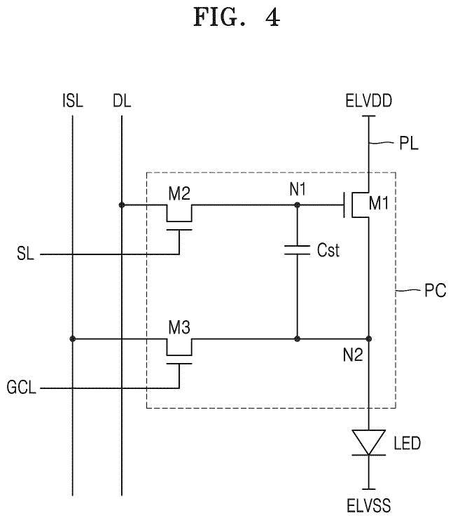

FIG. 4 is an equivalent circuit diagram illustrating a light-emitting diode included in a display apparatus and a sub-pixel circuit electrically connected to the light-emitting diode, according to one or more embodiments. A sub-pixel circuit PC of FIG. 4 may correspond to each of the first to third sub-pixel circuits PC1, PC2, and PC3 described with reference to FIG. 2, and a light-emitting diode LED of FIG. 4 may correspond to each of the first to third light-emitting diodes LED1, LED2, and LED3 described with reference to FIG. 2.

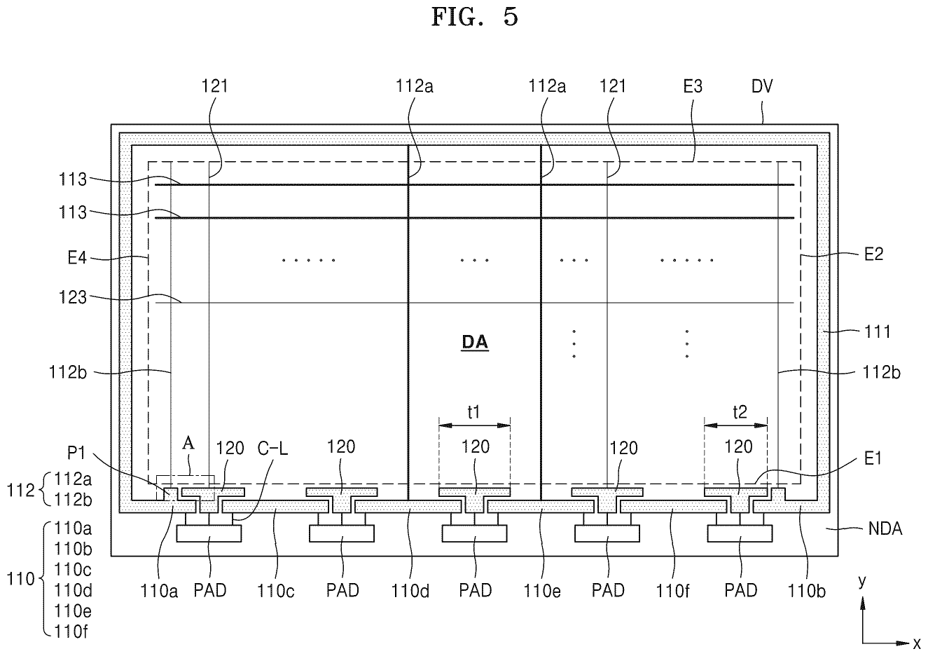

Referring to FIG. 4, a first electrode (e.g., a pixel electrode) of the light-emitting diode LED may be connected to the sub-pixel circuit PC, and a second electrode (e.g., a counter electrode) of the light-emitting diode LED may be electrically connected to a common voltage line described below with reference to FIG. 5 to receive a common voltage ELVSS. The light-emitting diode LED may emit light at a luminance corresponding to the amount of current supplied from the sub-pixel circuit PC.

The sub-pixel circuit PC may control the amount of current flowing through the light-emitting diode LED in response to a data signal. The sub-pixel circuit PC may include a first transistor M1, a second transistor M2, a third transistor M3, and a storage capacitor Cst.

Each of the first transistor M1, the second transistor M2, and the third transistor M3 may be an oxide semiconductor transistor including a semiconductor layer formed of an oxide semiconductor, or may be a silicon semiconductor transistor including a semiconductor layer formed of polysilicon. According to a type of a transistor, a first electrode may be one of a source electrode and a drain electrode, and a second electrode may be the remaining one of the source electrode and the drain electrode.

A first electrode of the first transistor M1 may be connected to a driving voltage line PL that supplies a driving voltage ELVDD, and a second electrode may be connected to the first electrode of the light-emitting diode LED. A gate electrode of the first transistor M1 may be connected to a first node N1. The first transistor M1 may control the amount of current flowing from the driving voltage ELVDD to the light-emitting diode LED in response to a voltage of the first node N1.

The second transistor M2 may be a switching transistor. A first electrode of the second transistor M2 may be connected to a data line DL, and a second electrode of the second transistor M2 may be connected to the first node N1. A gate electrode of the second transistor M2 may be connected to a scan line SL. The second transistor M2 may be turned on when a scan signal is applied to the scan line SL, to electrically connect the data line DL to the first node N1.

The third transistor M3 may be an initialization transistor and/or a sensing transistor. A first electrode of the third transistor M3 may be connected to a second node N2, and a second electrode may be connected to a sensing line ISL. A gate electrode of the third transistor M3 may be connected to a control line GCL.

The storage capacitor Cst may be connected between the first node N1 and the second node N2. For example, a first capacitor electrode of the storage capacitor Cst may be connected to the gate electrode of the first transistor M1, and a second capacitor electrode of the storage capacitor Cst may be connected to the first electrode of the light-emitting diode LED.

Although the first transistor M1, the second transistor M2, and the third transistor M3 are NMOSs in FIG. 4, the disclosure is not limited thereto. For example, at least one of the first transistor M1, the second transistor M2, and the third transistor M3 may be a PMOS.

Although three transistors are illustrated in FIG. 4, the disclosure is not limited thereto. The sub-pixel circuit PC may include four or more transistors.

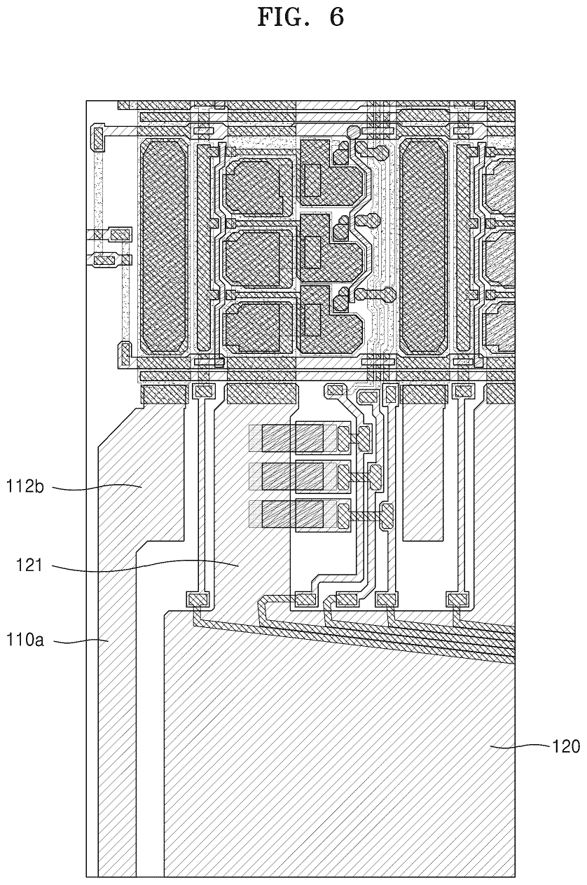

FIG. 5 is a plan view schematically illustrating a display apparatus, according to one or more embodiments. FIG. 6 is an enlarged plan view schematically illustrating a portion A of FIG. 5.

As described with reference to FIG. 1, the display apparatus DV may include the display area DA where a plurality of sub-pixels are located, and the non-display area NDA outside the display area DA. The non-display area NDA is an area where an image is not provided, a driver or a voltage wiring for providing an electrical signal or power to sub-pixel circuits may be located in the non-display area NDA, and a pad PAD to which an electronic device or a printed circuit board may be electrically connected may be included in the non-display area NDA.

Referring to FIGS. 5 and 6, a common voltage input (e.g., common voltage input unit) 110, a driving voltage input (e.g., driving voltage input unit) 120, and the pad PAD may be located in the non-display area NDA adjacent to a first edge E1 of the display area DA.

A plurality of common voltage inputs 110 may be provided along the first edge E1 of the display area DA. In this regard, in FIG. 5, a first common voltage input 110a and a second common voltage input 110b are respectively located at both ends of the first edge E1 of the display area DA, and third to sixth common voltage inputs 110c, 110d, 110e, and 110f are arranged at intervals along the first edge E1.

The first common voltage input 110a and the second common voltage input 110b may be connected to each other by a main common voltage line 111 extending along a second edge E2, a third edge E3, and a fourth edge E4 of the display area DA. In other words, the first common voltage input 110a, the second common voltage input 110b, and the main common voltage line 111 may be integrally formed with each other.

The common voltage inputs 110 and the main common voltage line 111 may be electrically connected to the second electrodes of the light-emitting diodes LED (see FIG. 4). For example, the second electrodes of the light-emitting diodes LED (see FIG. 4) may entirely cover the display area DA, and may extend to the non-display area NDA to directly contact the common voltage inputs 110 and a part of the main common voltage line 111.

Vertical common voltage lines 112 and horizontal common voltage lines 113 electrically connected to the common voltage input 110 and the main common voltage line 111 may be located in the display area DA. The vertical common voltage lines 112 may cross the display area DA in a second direction (e.g., a y direction) to electrically connect the common voltage input 110 to the main common voltage line 111. The vertical common voltage line 112 may include a first vertical common voltage line 112a located at a central portion of the display area DA, and a second vertical common voltage line 112b located at an edge of the display area DA. The first vertical common voltage lines 112a may those from among the vertical common voltage lines 112 not including the second vertical common voltage lines 112b located at the edge of the display area DA. The second vertical common voltage line 112b may be located closer to the non-display area NDA than the first vertical common voltage line 112a.

The horizontal common voltage lines 113 may extend in a first direction (e.g., an x direction) in the display area DA, and may be electrically connected to the vertical common voltage lines 112. When the size of the display area DA is large, the second electrode of the light-emitting diode LED (see FIG. 4) may cause a voltage drop in each part within the display area DA. For example, because the central portion of the display area DA is far from the common voltage inputs 110 and the main common voltage line 111, a voltage drop due to the resistance of the second electrode itself may occur, thereby lowering display quality. The vertical common voltage line 112 and the horizontal common voltage line 113 crossing the display area DA may be connected to the second electrode of the light-emitting diode in the display area DA, to reduce or prevent such a voltage drop as described above.

A plurality of driving voltage inputs 120 may be provided along the first edge E1 of the display area DA. As shown in FIG. 5, each of the driving voltage inputs 120 may be located between the common voltage inputs 110 spaced apart from each other. The pads PAD may correspond to the driving voltage inputs 120. For example, one driving voltage input 120, and the common voltage inputs 110 located on both sides of the driving voltage input 120 may be connected to one pad PAD through a connection line C-L.

The driving voltage input 120 may be electrically connected to a vertical driving voltage line 121 crossing the display area DA along the second direction (e.g., the y direction) and to a horizontal driving voltage line 123 crossing the display area DA along the first direction (e.g., the x direction). The vertical driving voltage line 121 may be the driving voltage line PL of FIG. 4. When the size of the display area DA is large, the vertical driving voltage line 121 may cause a voltage drop in one or more parts within the display area DA. For example, because a portion of the display area DA adjacent to the third edge E3 is far from the driving voltage input 120, a drop voltage may be caused by the resistance of the vertical driving voltage line 121 itself.

Accordingly, the horizontal driving voltage lines 123 crossing the display area DA along the first direction (e.g., the x direction) may be connected to the vertical driving voltage lines 121 to reduce or prevent such a voltage drop as described above.

In one or more embodiments, the first common voltage input 110a and/or the second common voltage input 110b, which may be the common voltage input 110 located at an edge of the non-display area NDA from among the common voltage inputs 110, may include a protrusion P1 protruding toward the display area DA. The protrusion P1 of the first common voltage input 110a and/or the second common voltage input 110b may extend to the second vertical common voltage line 112b located at the edge of the display area DA. In other words, the protrusion P1 of the first common voltage input 110a and/or the second common voltage input 110b may be integrally provided with the second vertical common voltage line 112b located at the edge of the display area DA. The protrusion P1 of the first common voltage input 110a and/or the second common voltage input 110b may be located on the same layer as the second vertical common voltage line 112b located at the edge of the display area DA. The third to sixth common voltage inputs 110c, 110d, 110e, and 110f located at a central portion of the non-display area NDA may be electrically connected to the first vertical common voltage lines 112a located at the central portion of the display area DA. The third to sixth common voltage inputs 110c, 110d, 110e, and 110f located at the central portion of the non-display area NDA may be located on the same layer as the first vertical common voltage lines 112a located at the central portion of the display area DA, and the third to sixth common voltage inputs 110c, 110d, 110e, and 110f may be electrically connected to the first vertical common voltage lines 112a through contact holes. The first vertical common voltage line 112a, the second vertical common voltage line 112b, and the common voltage input 110 may be located on the same layer.

When the vertical common voltage lines 112 located in the display area DA are electrically connected to the common voltage inputs 110 located in the non-display area NDA through contact holes, in an operation where a layer including the common voltage inputs 110 and the vertical common voltage lines 112 is manufactured during a display apparatus manufacturing process, the vertical common voltage lines 112 and the common voltage inputs 110 are not electrically connected, and thus, an open/short test between wirings may not be performed at that point. In one or more embodiments, when the first common voltage input 110a and/or the second common voltage input 110b located at the edge of the non-display area NDA includes the protrusion P1 toward the display area DA, and the second vertical common voltage lines 112b extend from the protrusion P 1 of the first common voltage input 110a and/or the second common voltage input 110b to be integrally provided with the first common voltage input 110a and/or the second common voltage input 110b, in an operation where a layer including the common voltage inputs 110 and the vertical common voltage lines 112 is manufactured during a display apparatus manufacturing process, there is a wiring capable of applying the common voltage ELVSS to the display area DA, and thus, an open/short test between wirings may be performed.

Because the first common voltage input 110a and/or the second common voltage input 110b located at the edge of non-display area NDA (e.g., a peripheral area) is integrally provided to the second vertical common voltage lines 112b connected to the first common voltage input 110a and/or the second common voltage input 110b, and is located at the edge of the display area DA, the first common voltage input 110a and/or the second common voltage input 110b may include the protrusion P1. Accordingly, a maximum length t2 of the driving voltage input 120 located at the edge of the non-display area NDA in the first direction (e.g., the x direction) may be less than a maximum length t1 of the driving voltage input 120 located at the central portion of the peripheral area in the first direction (e.g., the x direction).

The vertical driving voltage line 121 located in the display area DA and the driving voltage input 120 located in the non-display area NDA may be integrally provided, and the vertical driving voltage line 121 and the driving voltage input 120 may be located on the same layer. In an operation where a layer including the driving voltage input 120 and the vertical driving voltage line 121 is manufactured during a display apparatus manufacturing process, there may be a wiring capable of applying the driving voltage ELVDD to the display area DA.

According to one or more embodiments as described above, a display apparatus with improved reliability and quality may be implemented. However, the scope of the disclosure is not limited by this aspect.

It should be understood that embodiments described herein should be considered in a descriptive sense only and not for purposes of limitation. Descriptions of aspects within each embodiment should typically be considered as available for other similar aspects in other embodiments. While one or more embodiments have been described with reference to the figures, it will be understood by one of ordinary skill in the art that various changes in form and details may be made therein without departing from the spirit and scope as defined by the following claims, with functional equivalents thereof to be included therein.

What is claimed is:

1. A display apparatus comprising:
a substrate comprising a display area, and a peripheral area outside the display area;
a driving voltage input in the peripheral area;
a first vertical common voltage line and a second vertical common voltage line in the display area, and extending in a first direction, the second vertical common voltage line being at an edge of the display area; and
common voltage inputs in the peripheral area, spaced apart from the driving voltage input, and comprising a common voltage input at an edge of the peripheral area comprising a protrusion extending toward the display area and extending to the second vertical common voltage line.

2. The display apparatus of claim 1, wherein the protrusion is integral with the second vertical common voltage line.

3. The display apparatus of claim 1, wherein the protrusion is at a same layer as the second vertical common voltage line.

4. The display apparatus of claim 1, wherein the driving voltage input comprises a driving voltage input at the edge of the peripheral area, and a driving voltage input at a central portion of the peripheral area, and
wherein a maximum length of the driving voltage input at the edge of the peripheral area in a second direction crossing the first direction is less than a maximum length of the driving voltage input at the central portion of the peripheral area in the second direction.

5. The display apparatus of claim 1, wherein the second vertical common voltage line is closer to the peripheral area than the first vertical common voltage line.

6. The display apparatus of claim 1, wherein the driving voltage input is provided in plurality, and
wherein the driving voltage inputs and the common voltage inputs are alternately arranged along a second direction crossing the first direction.

7. The display apparatus of claim 1, further comprising a vertical driving voltage line in the display area, and extending in the first direction.

8. The display apparatus of claim 7, wherein the vertical driving voltage line is integral with the driving voltage input.

9. The display apparatus of claim 7, wherein the vertical driving voltage line is at a same layer as the driving voltage input.

10. The display apparatus of claim 1, wherein the first vertical common voltage line is electrically connected to one of the common voltage inputs through a contact hole.

11. The display apparatus of claim 1, further comprising a horizontal common voltage line in the display area, extending in a second direction crossing the first direction, and electrically connected to the first vertical common voltage line or the second vertical common voltage line.

12. The display apparatus of claim 11, further comprising a horizontal driving voltage line in the display area, extending in the second direction, and electrically connected to the vertical driving voltage line.

13. A display apparatus comprising:
a substrate comprising a display area, and a peripheral area outside the display area;
a driving voltage input in the peripheral area;
common voltage inputs in the peripheral area, and spaced apart from the driving voltage input; and
a first vertical common voltage line in the display area, extending in a first direction, and integral with and extending from one of the common voltage inputs at an edge of the peripheral area.

14. The display apparatus of claim 13, further comprising a second vertical common voltage line in the display area, extending in the first direction, and electrically connected to one of the common voltage inputs at a central portion of the peripheral area.

15. The display apparatus of claim 14, wherein the first vertical common voltage line, the second vertical common voltage line, and the common voltage inputs are at a same layer.

16. The display apparatus of claim 14, wherein the second vertical common voltage line and one of the common voltage inputs at the central portion of the peripheral area are electrically connected to each other through a contact hole.

17. The display apparatus of claim 14, wherein the first vertical common voltage line is closer to the peripheral area than the second vertical common voltage line.

18. The display apparatus of claim 13, further comprising a vertical driving voltage line in the display area and extending in the first direction.

19. The display apparatus of claim 18, wherein the first vertical common voltage line is integral with the driving voltage input.

20. The display apparatus of claim 13, wherein the driving voltage input comprises a driving voltage input at the edge of the peripheral area, and a driving voltage input at a central portion of the peripheral area, and
wherein a maximum length of the driving voltage input at the edge of the peripheral area in a second direction crossing the first direction is less than a maximum length of the driving voltage input at the central portion of the peripheral area in the second direction.
